(19) United States
(12) Patent Application Publication
(10) Pub. No.: US 2025/0118565 A1
(43) Pub. Date: Apr. 10, 2025

(54) METHOD OF MANUFACTURING SEMICONDUCTOR CHIP

(71) Applicant: Samsung Electronics Co., Ltd., Suwon-si (KR)

(72) Inventors: Hyunho Chu, Suwon-si (KR); Jiwon Shin, Suwon-si (KR); Kwangyong Lee, Suwon-si (KR); Minwoo Jeon, Suwon-si (KR)

(21) Appl. No.: 18/808,273

(22) Filed: Aug. 19, 2024

(30) Foreign Application Priority Data
Oct. 5, 2023 (KR) 10-2023-0132699

(51) Int. Cl. H01L 21/3065; H01L 21/683; H01L 21/78

(52) U.S. Cl. CPC H01L 21/3065; H01L 21/6836; H01L 21/78; H01L 2221/68327; H01L 2221/6834

(57) ABSTRACT

A method of manufacturing a semiconductor chip includes grinding a substrate that includes a device region and a scribe lane region, forming a protective coating layer on the substrate, plasma-thinning the substrate, and plasma-sawing the scribe lane region of the substrate. The plasma-thinning of the substrate and the plasma-sawing of the scribe lane region of the substrate are performed in-situ in a same chamber.

### REFERENCE TO RELATED APPLICATION

This application is based on and claims priority under 35 U.S.C. § 119 to Korean Patent Application No. 10-2023-0132699, filed on Oct. 5, 2023, in the Korean Intellectual Property Office, the disclosure of which is incorporated by reference herein in its entirety.

### BACKGROUND OF THE INVENTION

The inventive concepts relate to a method of manufacturing a semiconductor chip, and more particularly, to a method of manufacturing a semiconductor chip using thinning and plasma-sawing.

In accordance with the rapid development of the electronics industry and demands of users, smaller electronic products are being developed. Accordingly, there is a demand for a thinner semiconductor chip to be mounted in electronic products. As a thickness of a semiconductor chip is reduced, there is a need to improve the conventional methods of separating semiconductor chips from a wafer.

### SUMMARY OF THE INVENTION

The inventive concepts relate to a semiconductor chip manufacturing method capable of simply and inexpensively producing highly reliable semiconductor chips.

According to aspects of the inventive concepts, there is provided a method of manufacturing a semiconductor chip, the method including grinding a substrate that includes a device region and a scribe lane region, forming a protective coating layer on the substrate, plasma-thinning the substrate, and plasma-sawing the scribe lane region of the substrate. The plasma-thinning of the substrate and the plasma-sawing of the scribe lane region of the substrate may be performed in-situ in a same chamber.

According to aspects of the inventive concepts, there is provided a method of manufacturing a semiconductor chip, the method including grinding a substrate that includes a device region and a scribe lane region, forming a protective coating layer on the substrate, plasma-thinning the substrate, and plasma-sawing the scribe lane region of the substrate. The plasma-thinning of the substrate may be performed on a rear surface of the substrate, and the plasma-sawing of the scribe lane region of the substrate may be performed on a front surface of the substrate opposite the rear surface.

According to aspects of the inventive concepts, there is provided a method of manufacturing a semiconductor chip, the method including grinding a rear surface of a substrate, the substrate including a device region and a scribe lane region, forming a protective coating layer on a front surface of the substrate opposite the rear surface, forming a groove in the protective coating layer and an active layer, the active layer being provided on the front surface of the substrate, plasma-thinning the rear surface of the substrate, and plasma-sawing the scribe lane region on the front surface of the substrate. The plasma-thinning of the rear surface of the substrate and the plasma-sawing of the scribe lane region on the front surface of the substrate may be performed in-situ in a same chamber.

### BRIEF DESCRIPTION OF THE DRAWINGS

Embodiments will be more clearly understood from the following detailed description taken in conjunction with the accompanying drawings in which:

FIG. 1 is a flowchart illustrating a method of manufacturing a semiconductor chip according to embodiments; and

FIGS. 2 to 8 are views illustrating operations of a method of manufacturing a semiconductor chip according to embodiments.

### DETAILED DESCRIPTION

Hereinafter, example embodiments will be described in detail with reference to the accompanying drawings. Like reference numerals refer to like elements, and their repetitive descriptions are omitted.

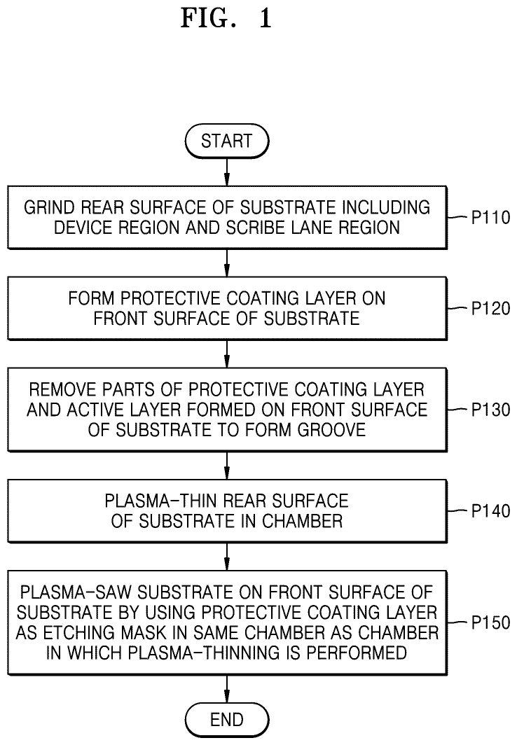

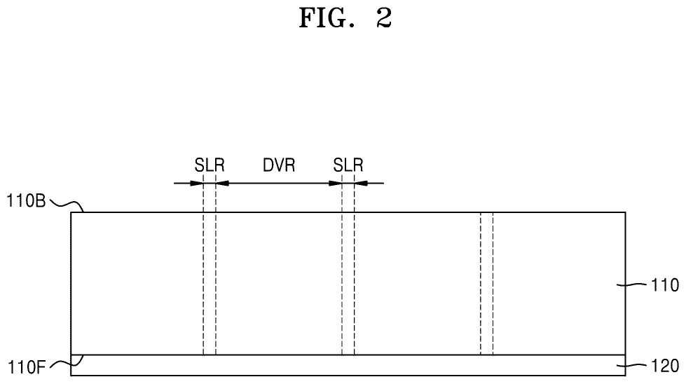

FIG. 1 is a flowchart illustrating a method of manufacturing a semiconductor chip 100a according to embodiments. FIGS. 2 to 8 are views illustrating operations of the method of manufacturing the semiconductor chip 100a according to embodiments. Specifically, FIGS. 2 to 8 are cross-sectional views for illustrating the operations of the method of manufacturing the semiconductor chip 100a of FIG. 1.

Referring to FIGS. 1 and 2, first, a substrate 110 including device regions DVR and scribe lane regions SLR may be provided. The substrate 110 may be provided on a chuck table (not shown) and supported by the chuck table. At this time, the substrate 110 may be provided on the chuck table so that a front surface 110F of the substrate 110 faces a top surface of the chuck table. Accordingly, as shown in FIG. 2, a rear surface 110B of the substrate 110 may be positioned above the front surface 110F of the substrate 110 in a vertical direction. For example, the vertical direction may be a direction perpendicular to the front surface 110F of the substrate 110.

The substrate 110 may include, for example, a semiconductor material such as silicon (Si). The substrate 110 may include a semiconductor element such as germanium (Ge), or a compound semiconductor such as silicon carbide (SiC), gallium arsenide (GaAs), indium arsenide (InAs), or indium phosphate (InP).

The substrate 110 may be provided as a bulk wafer or an epitaxial layer. The substrate 110 may be formed of a silicon on insulator (SOI) substrate, a gallium-arsenide substrate, a silicon germanium substrate, a ceramic substrate, a quartz substrate, or a glass substrate for a display.

The substrate 110 may include a conductive region, for example, an impurity-doped well or an impurity-doped structure. In addition, the substrate 110 may have one of various device isolation structures such as a shallow trench isolation (STI) structure.

The substrate 110 may have the front surface 110F and the rear surface 110B opposite to the front surface 110F. The front surface 110F of the substrate 110 may correspond to an active surface of the substrate 110, and the rear surface 110B of the substrate 110 may correspond to an inactive surface of the substrate 110. It will be appreciated that the front surface 110F and the rear surface 110B are surfaces of the substrate 110 opposite to each other (e.g., in the vertical direction). As such, these surfaces will be referred to as the front surface 110F and the rear surface 110B throughout the Specification, even though parts of the substrate 110 may be removed by processes discussed herein.

An active layer 120 may be formed on the front surface 110F of the substrate 110. In the device regions DVR of the substrate 110, the active layer 120 may include a plurality of various types of individual devices. The plurality of individual devices may include various microelectronic devices, for example, a metal-oxide-semiconductor field effect transistor (MOSFET) such as a complementary metal-oxide semiconductor (CMOS) transistor, a system large scale integration (LSI), an image sensor such as a CMOS imaging sensor (CIS), a micro-electro-mechanical system (MEMS), an active element, a passive element, and a memory device such as a dynamic random access memory (DRAM) device, a static random access memory (SRAM) device, a flash memory device, an electrically erasable and programmable read-only memory (EEPROM) device, a phase-change random access memory (PRAM) device, a magnetic random access memory (MRAM) device, or a resistive random access memory (RRAM) device. The plurality of individual devices may be electrically connected to the conductive region of the substrate 110. Each of the plurality of individual devices may be insulated from other neighboring individual devices by an insulating layer (not shown).

In the scribe lane regions SLR of the substrate 110, the active layer 120 may include components such as a test element group (TEG) and an alignment mark. At this time, because the scribe lane regions SLR of the substrate 110 will be at least partially removed by a sawing process later, a semiconductor device involved in operations of the device regions DVR other than a test may not be included in the active layer 120 in the scribe lane regions SLR.

In embodiments, a protective coating layer (not shown) may be formed on the active layer 120. The protective coating layer may be on (e.g., may cover) the entire active layer 120 and may have the same shape as the substrate 110, but may not protrude to the outside (e.g., beyond sides) of the substrate 110. The protective coating layer may prevent the active layer 120 from being damaged.

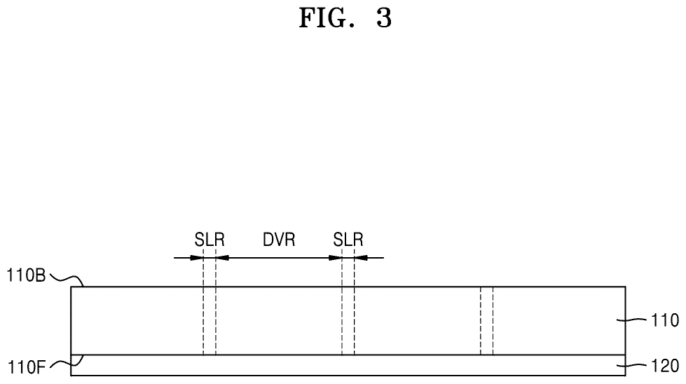

Referring to FIGS. 1 and 3, the rear surface 110B of the substrate 110 may be ground in operation P110. The grinding process P110 may be performed by contacting a grinding device (not shown) with the rear surface 110B of the substrate 110 and flipping the chuck table supporting the grinding device and/or the substrate 110 to grind the rear surface 110B of the substrate 110 with the grinding device.

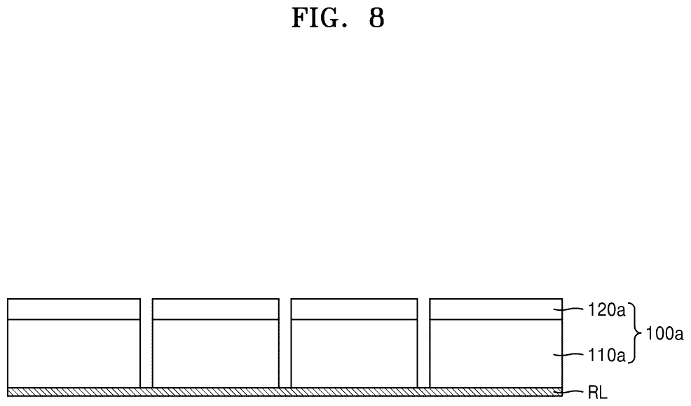

Parts of the substrate 110 may be removed by the grinding process P110 so that a thickness of the substrate 110 may be reduced. At this time, the thickness of the substrate 110 after the grinding process P110 is performed may be greater than a thickness of a chip substrate 110a (see FIG. 8) of the semiconductor chip 100a (see FIG. 8).

The grinding process P110 may include, for example, a chemical mechanical polishing (CMP) process.

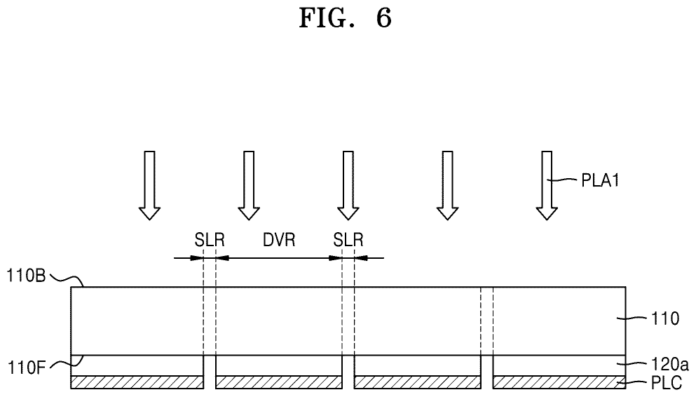

Meanwhile, while the grinding process P110 is performed, microcracks (not shown) may occur on the rear surface 110B of the ground substrate 110. The microcracks may deteriorate a mechanical strength of the substrate 110. The microcracks may be removed together with parts of the substrate 110 by plasma-thinning in a plasma-thinning process P140 to be described later with reference to FIGS. 1 and 6.

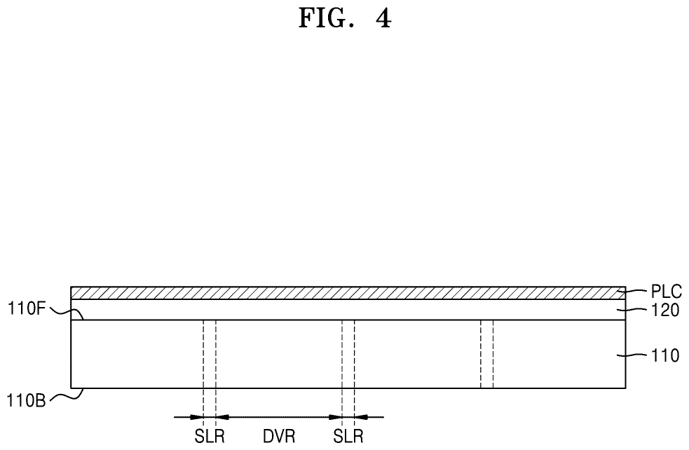

Referring to FIGS. 1 and 4, the protective coating layer PLC may be formed on the front surface 110F of the substrate 110 in operation P120. Specifically, first, the substrate 110 may be flipped so that the front surface 110F of the substrate 110 is positioned above the rear surface 110B of the substrate 110 in the vertical direction. Next, the protective coating layer PLC may be coated on the active layer 120 formed on the front surface 110F of the substrate 110.

The protective coating layer PLC may be formed to be on (e.g., to cover) the entire active layer 120, but may not protrude to the outside (e.g., beyond sides) of the active layer 120. The active layer 120 may be between the protective coating layer PLC and the substrate 110.

In embodiments, the protective coating layer PLC may be formed by a spin coating process, a slit coating process, a dip coating process, a spray coating process, or an inkjet printing process. However, the inventive concepts are not limited thereto.

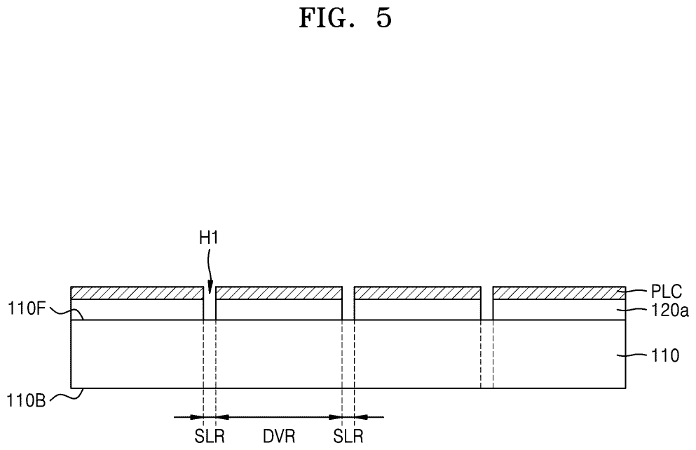

Referring to FIGS. 1 and 5, parts of the protective coating layer PLC and the active layer 120 may be removed in operation P130.

Parts of the protective coating layer PLC and the active layer 120 may be removed by, for example, a concentrated laser beam. By removing parts of the protective coating layer PLC and the active layer 120, grooves H1 that pass through the protective coating layer PLC and the active layer 120 in the vertical direction may be formed. The grooves H1 may expose parts of the front surface 110F of the substrate 110 on bottom surfaces of the grooves H1.

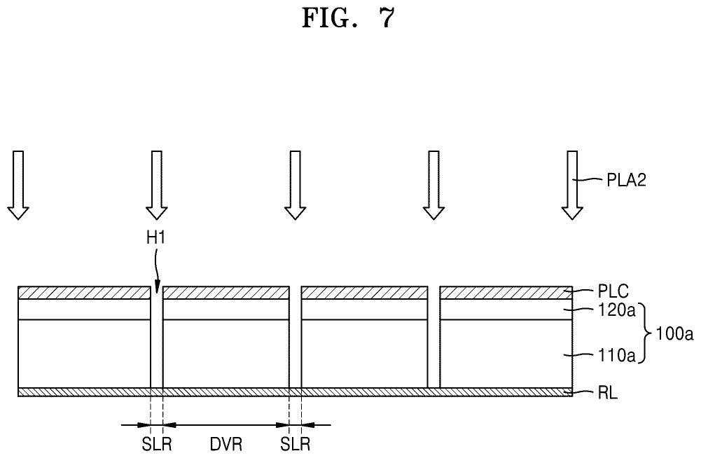

In embodiments, the grooves H1 may be formed to overlap the scribe lane regions SLR of the substrate 110 in the vertical direction. As used herein, “an element A overlaps an element B in a direction X” (or similar language) means that there is at least one line that extends in the direction X and intersects both the elements A and B. At this time, the grooves H1 may overlap regions in which the substrate 110 is sawed in a plasma-sawing process P150 of the substrate 110 to be described later with reference to FIGS. 1 and 7.

Meanwhile, when parts of the active layer 120 positioned on the scribe lane regions SLR of the substrate 110 are removed, only remaining parts of the active layer 120 positioned on the device regions DVR of the substrate 110 may remain. At this time, the remaining parts of the active layer 120 positioned on the device regions DVR may be defined as chip active layers 120a. The chip active layers 120a may be horizontally spaced apart from one another with the grooves H1 extending in the vertical direction therebetween, and each of the chip active layers 120a may constitute the semiconductor chip 100a together with each of the chip substrates 110a to be described later with reference to FIGS. 1 and 7.

In other embodiments, the process P110 of grinding the rear surface 110B of the substrate 110 described with reference to FIGS. 1 and 3 may be performed after the process P120 of forming the protective coating layer PLC described with reference to FIGS. 1 and 4 and after the process P130 of removing parts of the protective coating layer PLC and the active layer 120 described with reference to FIGS. 1 and 5 are performed. That is, the process P110 may be performed after the processes P120 and P130. For example, unlike what was described above with reference to FIGS. 1 and 2, the substrate 110 may be provided on the chuck table so that the rear surface 110B of the substrate 110 faces the top surface of the chuck table and the protective coating layer PLC may be formed on the front surface 110F of the substrate 110 in operation P120, parts of the protective coating layer PLC and the active layer 120 may be removed to form the grooves H1 in operation P130, and, after the substrate 110 is flipped so that the rear surface 110B of the substrate 110 is positioned above the front surface 110F of the substrate 110 in the vertical direction, the rear surface 110B of the substrate 110 may be ground in operation P110.

Referring to FIGS. 1 and 6, the rear surface 110B of the substrate 110 may be plasma-thinned in operation P140. Specifically, after the result of FIG. 5, first, the substrate 110 may be flipped so that the rear surface 110B of the substrate 110 is positioned above the front surface 110F of the substrate 110 in the vertical direction. Next, the flipped substrate 110 may be provided into a chamber of a plasma processing device. Next, the rear surface 110B of the substrate 110 provided in the chamber may be plasma-thinned.

The plasma processing device may be configured to perform a process using plasma. For example, the plasma processing device may include a chamber configured to provide a space in which plasma processing is performed, a support table configured to support the substrate 110 in the chamber, a gas supply device configured to supply a plasma gas into the chamber, a lower electrode positioned in the chamber, and a voltage supply device configured to apply a voltage to the lower electrode. For example, the plasma processing device may include an inductively coupled plasma (ICP) processing device or a capacitively coupled plasma (CCP) processing device. However, the inventive concepts are not limited thereto.

In embodiments, the plasma processing device may include a substrate flip device configured to flip the substrate 110 provided in the chamber. The substrate flip device may include, for example, a flip picker that picks up the substrate 110. The substrate flip device may adsorb and hold the substrate 110. In addition, the substrate flip device may flip the substrate 110 while holding the substrate 110 to invert the substrate 110 up and down.

In embodiments, the plasma processing device may include a tape attachment device configured to attach a dicing tape RL (see FIG. 7) to the substrate 110 provided in the chamber. The tape attachment device may attach the dicing tape RL to the substrate 110.

In embodiments, the plasma-thinning may include a process of etching the rear surface 110B of the substrate 110 by using a first plasma PLA1. In this case, parts of the substrate 110 may be removed by the plasma-thinning process P140 together with the microcracks that may occur on the rear surface 110B of the substrate 110 in the grinding process P110 described with reference to FIGS. 1 and 3.

In other embodiments, in the plasma-thinning process P140, after the substrate 110 is provided into the chamber of the plasma processing device, the substrate 110 provided in the chamber may be flipped. That is, unlike what was described above with reference to FIGS. 1 and 6, after the substrate 110 is first provided into the plasma chamber in the plasma-thinning process P140 and the substrate 110 provided in the chamber is flipped so that the rear surface 110B of the substrate 110 is positioned above the front surface 110F of the substrate 110 in the vertical direction by using the substrate flip device included in the plasma processing device, the rear surface 110B of the substrate 110 provided in the chamber may be plasma-thinned. In other words, instead of flipping the substrate 110 before it is provided in the chamber, the substrate 110 may be flipped after it is provided in the chamber using the substrate flip device so that the rear surface 110B of the substrate 110 is positioned above the front surface 110F of the substrate 110 in the vertical direction.

Referring to FIGS. 1 and 7, the substrate 110 may be plasma-sawed in operation P150. Specifically, after the rear surface 110B of the substrate 110 is plasma-thinned (see FIG. 6), the substrate flip device in the chamber may be used to flip the substrate 110 so that the front surface 110F of the substrate 110 is positioned above the rear surface 110B of the substrate 110 in the vertical direction, and the dicing tape RL may be formed on the rear surface 110B of the substrate 110 by using the tape attachment device in the chamber. The scribe lane regions SLR of the substrate 110 may then be plasma-sawed by using the protective coating layer PLC formed on the front surface 110F of the substrate 110 as an etching mask.

As the substrate 110 is plasma-sawed, the grooves H1 may extend into the substrate 110 in the vertical direction. Accordingly, the grooves H1 may pass through the substrate 110 in the vertical direction and may expose parts of the dicing tape RL attached to the substrate 110. Meanwhile, when the scribe lane regions SLR of the substrate 110 are cut off by the plasma-sawing process P150 of the substrate 110, the scribe lane regions SLR of the substrate 110 are removed, and only the device regions DVR of the substrate 110 may remain. At this time, the remaining device regions DVR of the substrate 110 may be defined as the chip substrates 110a. The chip substrates 110a are horizontally spaced apart from one another with the grooves H1 extending in the vertical direction therebetween, and each of the chip substrates 110a may constitute the semiconductor chip 100a together with each of the chip active layers 120a.

The dicing tape RL formed on the rear surface 110B of the substrate 110 may be on (e.g., may cover) the entire rear surface 110B of the substrate 110, and may have the same shape as a shape of the substrate 110, but may not protrude to the outside (e.g., beyond sides) of the substrate 110. The dicing tape RL may include a tape that has elasticity and loses adhesiveness by, for example, irradiating heat or ultraviolet rays. The dicing tape RL may include, for example, an ultraviolet (UV) tape. The dicing tape RL may function to fix the chip substrates 110a during the process of sawing the substrate 110.

In embodiments, the plasma-sawing process P150 may be performed in the same chamber as the chamber in which the plasma-thinning process P140 described with reference to FIGS. 1 and 6 is performed. That is, the plasma-thinning process P140 and the plasma-sawing process P150 may be in-situ processes performed in the same chamber. For example, the plasma-thinning process P140 and the plasma-sawing process P150 may be performed in the same fabrication environment (i.e., the same chamber) without the substrate 110 being removed therefrom.

Specifically, the substrate 110 provided into the chamber before the plasma-thinning process P140 is performed is not taken out of the chamber even after the plasma-thinning process P140 is completed, and may be taken out of the chamber only after being flipped in the chamber by the substrate flip device and sawed by the plasma-sawing process P150.

In embodiments, the plasma-sawing process P150 may include an etching process using a second plasma PLA2. For example, the plasma-sawing process P150 may include a process of sawing the scribe lane regions SLR of the substrate 110 by using the second plasma PLA2 with the protective coating layer PLC as the etching mask. In this case, the second plasma PLA2 may include a plasma generated by a plasma gas having a high etch selectivity for a material constituting the substrate 110.

The first plasma PLA1 used in the plasma-thinning process P140 and the second plasma PLA2 used in the plasma-sawing process P150 may be generated by using the same plasma gas. For example, the first plasma PLA1 and the second plasma PLA2 may be generated by using an oxygen gas. However, the inventive concepts are not limited thereto, and the first plasma PLA1 and the second plasma PLA2 may be generated by using different plasma gases.

In embodiments, the plasma-sawing process P150 may be performed on the front surface 110F (see FIG. 6) of the substrate 110 exposed by the grooves H1. That is, the plasma-sawing process P150 may be performed in a direction from the front surface 110F of the substrate 110 toward the rear surface 110B of the substrate 110. Because the plasma-sawing process P150 is performed on the front surface 110F of the substrate 110 opposite to the rear surface 110B of the substrate 110 on which the plasma-thinning process P140 is performed, it may be easier to control process conditions of the plasma-thinning process P140 and the plasma-sawing process P150 than when both the plasma-thinning process P140 and the plasma-sawing process P150 are performed on the same surface of the substrate 110.

In other embodiments, in the plasma-sawing process P150, after the dicing tape RL is first formed on the rear surface 110B of the substrate 110 by using the tape attachment device arranged in the chamber, the substrate 110 may be flipped so that the front surface 110F of the substrate 110 is positioned above the rear surface 110B of the substrate 110 in the vertical direction by using the substrate flip device in the chamber. That is, unlike what was described above with reference to FIGS. 1 and 7, after the dicing tape RL is first formed on the rear surface 110B of the substrate 110 by using the tape attachment device in the chamber and the substrate 110 is flipped so that the front surface 110F of the substrate 110 is positioned above the rear surface 110B of the substrate 110 in the vertical direction by using the substrate flip device in the chamber, the substrate 110 may be plasma-sawed by cutting off the scribe lane regions SLR of the substrate 110. In other words, instead of flipping the substrate 110 before the dicing tape RL is formed on the rear surface 110B of the substrate 110, the dicing tape RL may formed on the rear surface 110B of the substrate 110 first using the tape attachment device, and then the substrate 110 may be flipped using the substrate flip device so that the front surface 110F of the substrate 110 is positioned above the rear surface 110B of the substrate 110 in the vertical direction.

Referring to FIGS. 1 and 8, the protective coating layer PLC (see FIG. 7) formed on the semiconductor chip 100a sawed by the plasma-sawing process P150 may be removed. The protective coating layer PLC may be removed, for example, by a cleaning process using deionized (DI) water. However, the inventive concepts are not limited thereto. In embodiments, the protective coating layer PLC may be removed outside of the plasma chamber in which the plasma-thinning process P140 and the plasma-sawing process P150 are performed. That is, the semiconductor chips 100a sawed by the plasma-sawing process P150 and the dicing tape RL to which the semiconductor chips 100a are attached are taken out of the chamber of the plasma processing device after the plasma-sawing process P150 is completed and the protective coating layer PLC may be removed from the semiconductor chips 100a after the semiconductor chips 100a are taken out of the chamber. For example, the protective coating layer PLC may be removed in a chamber different from the chamber in which the substrate 110 is plasma-thinned in the plasma-thinning process P140 and the scribe lane region SLR of the substrate 110 is plasma-sawed in the plasma-sawing process P150.

The semiconductor chip 100a may include, for example, a memory chip or a logic chip. The memory chip may include, for example, a volatile memory chip such as dynamic random access memory (DRAM) or static random access memory (SRAM), or a non-volatile memory chip such as phase-change random access memory (PRAM), magnetoresistive random access memory (MRAM), ferroelectric random access memory (FeRAM), or resistive random access memory (RRAM). In addition, the logic chip may include, for example, a microprocessor, an analog element, or a digital signal processor.

The method of manufacturing the semiconductor chip according to embodiments may include the process of plasma-thinning the rear surface of the substrate and the process of sawing the plasma-thinned substrate on the front surface of the substrate opposite to the rear surface of the substrate by using plasma. At this time, the plasma-thinning process and the plasma-sawing process of the substrate may be performed in-situ in the same chamber. Therefore, both the plasma-thinning process and the plasma-sawing process of the substrate may be performed by using a single plasma processing device so that it is possible to reduce manufacturing costs of the semiconductor chip. In addition, because the plasma-thinning process and the substrate sawing process using plasma are performed continuously in the same chamber without taking out the substrate brought into the chamber between processes, both the plasma-thinning process and the substrate sawing process using plasma may be performed by performing a plasma process setup only once. Accordingly, the semiconductor chip may be manufactured more quickly. In addition, because the plasma-thinning process to remove the microcracks in the substrate and the substrate sawing process using plasma are performed on opposite sides of the substrate, the process conditions may be more easily controlled compared to a case in which the plasma-thinning process and the substrate sawing process using plasma are performed on the same side of the substrate. Accordingly, the semiconductor chip may be simply manufactured.

As used herein, it will be understood that the terms “comprises”, “comprising”, “includes”, “including”, “has”, “having” and any other variations thereof specify the presence of the stated features, steps, operations, elements, components, and/or groups but do not preclude the presence or addition of one or more other features, steps, operations, elements, components, and/or groups thereof.

While the inventive concepts have been particularly shown and described with reference to example embodiments thereof, it will be understood that various changes in form and details may be made therein without departing from the scope of the following claims.

What is claimed is:

1. A method of manufacturing a semiconductor chip, the method comprising:
grinding a substrate that includes a device region and a scribe lane region;
forming a protective coating layer on the substrate;
plasma-thinning the substrate; and
plasma-sawing the scribe lane region of the substrate, wherein the plasma-thinning of the substrate and the plasma-sawing of the scribe lane region of the substrate are performed in-situ in a same chamber.

2. The method of claim 1, wherein the plasma-thinning of the substrate comprises removing a part of the substrate by plasma processing a rear surface of the substrate.

3. The method of claim 1, wherein the plasma-sawing of the scribe lane region of the substrate comprises plasma-sawing the scribe lane region on a front surface of the substrate.

4. The method of claim 1, further comprising flipping the substrate after the plasma-thinning of the substrate and before the plasma-sawing of the scribe lane region of the substrate.

5. The method of claim 4, further comprising forming a dicing tape on the substrate after the flipping of the substrate.

6. The method of claim 1, wherein the forming of the protective coating layer on the substrate comprises forming the protective coating layer on a front surface of the substrate.

7. The method of claim 1, further comprising forming a groove in the protective coating layer and an active layer after the forming of the protective coating layer on the substrate, wherein the active layer is between the substrate and the protective coating layer.

8. The method of claim 7, wherein the groove overlaps the scribe lane region of the substrate in a vertical direction perpendicular to a front surface of the substrate.

9. The method of claim 7, wherein the forming of the groove in the protective coating layer and the active layer comprises etching the protective coating layer and the active layer using a laser.

10. The method of claim 1, further comprising removing the protective coating layer after the plasma-sawing of the scribe lane region of the substrate, wherein the removing of the protective coating layer is performed in a chamber different from the chamber in which the substrate is plasma-thinned and the scribe lane region of the substrate is plasma-sawed.

11. A method of manufacturing a semiconductor chip, the method comprising:
grinding a substrate that includes a device region and a scribe lane region;
forming a protective coating layer on the substrate;
plasma-thinning the substrate; and
plasma-sawing the scribe lane region of the substrate,
wherein the plasma-thinning of the substrate is performed on a rear surface of the substrate, and the plasma-sawing of the scribe lane region of the substrate is performed on a front surface of the substrate opposite the rear surface.

12. The method of claim 11, wherein the plasma-thinning of the substrate and the plasma-sawing of the scribe lane region of the substrate are performed in-situ in a same chamber.

13. The method of claim 11, further comprising flipping the substrate after the plasma-thinning of the substrate and before the plasma-sawing of the scribe lane region of the substrate.

14. The method of claim 13, further comprising forming a dicing tape on the rear surface of the substrate after the flipping of the substrate.

15. The method of claim 11, further comprising forming a groove in the protective coating layer and an active layer after the forming of the protective coating layer on the substrate,
wherein the protective coating layer is formed on the front surface of the substrate,
wherein the active layer is between the front surface of the substrate and the protective coating layer, and
wherein the forming of the groove comprises removing a part of the protective coating layer and the active layer using a laser.

16. The method of claim 15, wherein the groove overlaps the scribe lane region of the substrate in a vertical direction perpendicular to the front surface of the substrate, and wherein the groove exposes the front surface of the substrate.

17. The method of claim 11, further comprising removing the protective coating layer after the plasma-sawing of the scribe lane region of the substrate, wherein the removing of the protective coating layer is performed in a chamber different from a chamber in which the substrate is plasma-thinned and the scribe lane region of the substrate is plasma-sawed.

18. A method of manufacturing a semiconductor chip, the method comprising:
grinding a rear surface of a substrate, the substrate including a device region and a scribe lane region;
forming a protective coating layer on a front surface of the substrate opposite the rear surface;
forming a groove in the protective coating layer and an active layer, the active layer being provided on the front surface of the substrate;
plasma-thinning the rear surface of the substrate; and
plasma-sawing the scribe lane region on the front surface of the substrate, wherein the plasma-thinning of the rear surface of the substrate and the plasma-sawing of the scribe lane region on the front surface of the substrate are performed in-situ in a same chamber.

19. The method of claim 18, further comprising:
flipping the substrate after the plasma-thinning of the rear surface of the substrate and before the plasma-sawing of the scribe lane region on the front surface of the substrate; and
forming a dicing tape on the rear surface of the substrate after the flipping of the substrate.

20. The method of claim 19, further comprising removing the protective coating layer after the plasma-sawing of the scribe lane region on the front surface of the substrate, wherein the removing of the protective coating layer is performed in a chamber different from the chamber in which the rear surface of the substrate is plasma-thinned and the scribe lane region of the substrate is plasma-sawed.
